(19) United States
(12) Patent Application Publication
(10) Pub. No.: US 2007/0004225 A1
(43) Pub. Date: Jan. 4, 2007

(54) Low-temperature catalyzed formation of segmented nanowire of dielectric material

(76) Inventors: Donghui Lu, San Jose, CA (US); Zhan Chen, Aurora, IL (US)

Correspondence Address: INTEL CORPORATION;c/o INTELLEVATE, LLC, P.O. BOX 52050, MINNEAPOLIS, MN, 55402, US

(21) Appl. No.: 11/174,076

(22) Filed: Jun. 30, 2005

(51) Int. Cl. H01L 21/469

(52) U.S. Cl. 438/778; 438/792; 977/762; 977/891

(57) ABSTRACT

The present invention discloses a method of forming a segmented nanowire including: providing a substrate; pre-cleaning the substrate; pre-treating the substrate; forming and placing a catalyst over the substrate; and forming the segmented nanowire over the catalyst with recurring pulses of plasma-enhanced chemical vapor deposition (PECVD) of a dielectric material.

### BACKGROUND OF THE INVENTION

1. Field of the Invention

The present invention relates to the field of semiconductor integrated circuit (IC) manufacturing, and more specifically, to a nanowire of a dielectric, such as silicon nitride, and a method of forming the nanowire of a dielectric at a low temperature.

2. Discussion of Related Art

Nanowires are very small structures that have many potential applications due to their interesting optoelectronic properties. In particular, nanowires have a very large ratio of surface area relative to volume so they may be useful as gas detectors or sensors, such as for chemical or biological applications. Furthermore, their large aspect ratio of length relative to diameter (low dimensionality) also make them useful as field emitters for flat panel displays.

Nanowires may also be used for forming a light-emitting diode (LED) or a field-effect transistor (FET). However, conventional methods of forming nanowires may not be compatible with current processes for manufacturing electronic devices. As an example, the methods of forming nanowires may involve very high temperatures.

Thus, a need may exist for a new method of forming nanowires that may be integrated with existing processes for fabricating the electronic devices.

### BRIEF DESCRIPTION OF THE DRAWINGS

FIG. 1 is an illustration of catalyst formed and placed at certain locations over features at a surface of a layer over a substrate according to an embodiment of the present invention.

FIG. 2 is an illustration of various layouts of catalyst at a surface of a layer over a substrate according to an embodiment of the present invention.

FIG. 3 is an illustration of various spatial arrangements of segments of nanowires connected to a substrate according to an embodiment of the present invention.

FIG. 4 is an illustration of segmented nanowires with various structures and stiffnesses that are connected to a substrate according to an embodiment of the present invention.

### DETAILED DESCRIPTION OF THE PRESENT INVENTION

In the following description, numerous details, such as specific materials, dimensions, and processes, are set forth in order to provide a thorough understanding of the present invention. However, one skilled in the art will realize that the invention may be practiced without these particular details. In other instances, well-known semiconductor equipment and processes have not been described in particular detail so as to avoid obscuring the present invention.

The present invention discloses a method of forming a segmented nanowire of a dielectric material, such as silicon nitride, over a substrate. The present invention also discloses a segmented nanowire of a dielectric material, such as silicon nitride, located over a substrate.

A method to form a segmented nanowire of a dielectric material, such as silicon nitride, over a substrate according to various embodiments of the present invention will be described next. In an embodiment of the present invention, the substrate may include a material that is homogeneous. In an embodiment of the present invention, the substrate may include two or more chemically or physically distinct materials. In an embodiment of the present invention, the substrate may include a patterned stack of two or more materials.

In an embodiment of the present invention, the substrate may include an electrical conductor, such as copper. In an embodiment of the present invention, the substrate may include an electrical insulator, such as low-k (dielectric constant) material. In an embodiment of the present invention, the substrate may include a semiconductor, such as silicon-germanium. In an embodiment of the present invention, the substrate may be doped.

In an embodiment of the present invention, the substrate may include a semiconductor wafer. In an embodiment of the present invention, the substrate may include a silicon-on-insulator (SOI) wafer. In an embodiment of the present invention, the substrate may include an integrated circuit (IC) chip or die. In an embodiment of the present invention, the substrate may include bonded wafers. In an embodiment of the present invention, the substrate may include stacked chips. In an embodiment of the present invention, the substrate may include a package. In an embodiment of the present invention, the substrate may include a microelectromechanical system (MEMS).

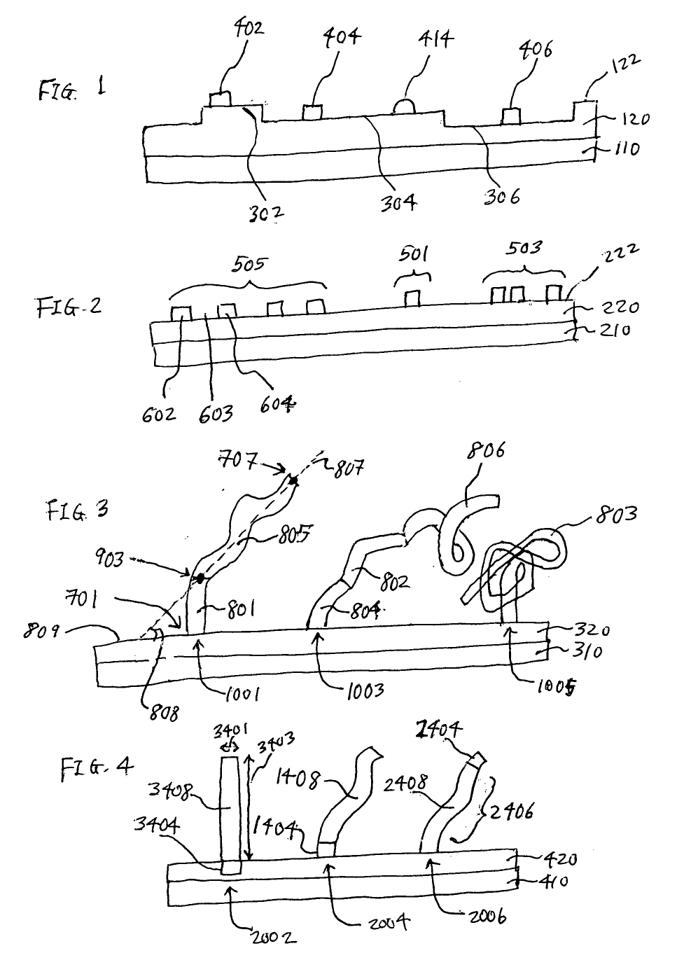

As shown in an embodiment of the present invention in FIG. 1, the substrate 110 may include a layer 120. In an embodiment of the present invention, the layer 120 may include a surface 122 with features that may be protruding 302, recessed 306, or flush 304 with the surface 122. The features may include grooves, holes, or steps. The walls of the features may meet the surface 122 at angles that may be acute, right, or obtuse.

First, the substrate 110 may be pre-cleaned to remove a contaminant. In particular, a contaminant, such as a metal, that may serve as a catalyst should be removed. The contaminant may be organic, inorganic, or metallic. The contaminant may be a particle, a flake, or a film. The contaminant may be attached to the surface 122 of the layer 120 over the substrate 110 by covalent bonds, ionic bonds, physisorption, or chemisorption.

In an embodiment of the present invention, the pre-clean may include a brush clean, roller clean, or high-pressure jet. In an embodiment of the present invention, the pre-clean may include immersion, spray, or cryogenic aerosol. The pre-clean may include an acid, base, solvent, or oxidizer, such as a peroxide or persulfate.

Second, the substrate 110 may be pre-treated to modify the surface 122 of the layer 120, such as physically or chemically, to improve adhesion of a catalyst. The pre-treatment may include a thermal treatment, such as with a bake or anneal. The pre-treatment may include a low-pressure treatment, such as with a vacuum. The pre-treatment may include a radiation treatment, such as with ultraviolet light. The pre-treatment may include a plasma treatment, such as with free radicals.

The pre-treatment may include a bombardment treatment, such as sputtering with particles. The particles may be neutral, such as atoms or molecules, or charged, such as electrons or ions. The particles may form a beam or shower.

The pre-treatment may include a bombardment treatment, such as ion implantation with a species. The species may be charged, such as ions. In an embodiment of the present invention, the layer 120 over the substrate 110 may be ion implanted, with a species to damage, amorphize, insulate, or dope an underlying region.

In an embodiment of the present invention, the ion implantation may be a blanket implant. In an embodiment of the present invention, the ion implantation may be a pattern implant, such as performed with a photoresist mask or a hard mask.

In an embodiment of the present invention, the ion implantation may be followed subsequently, after any photoresist has been removed, by a thermal cycle, such as a furnace anneal, rapid anneal, or spike anneal.

The ion-implanted region may be damaged, such as with bubble defects. In various embodiments of the present invention, the ion-implanted species may include an element from column VIII A of the periodic table, such as helium, neon, argon, or xenon.

The ion-implanted region may be insulated. In various embodiments of the present invention, the ion-implanted species may include nitrogen or oxygen.

The ion-implanted region may be doped. In an embodiment of the present invention, the ion-implanted species may include an element from an upper portion of column III A of the periodic table, such as boron, or an element from a lower portion of column V A of the periodic table, such as arsenic or antimony. Boron, arsenic, and antimony are metalloids.

Metalloids are elements that possess properties that are intermediate between metals and nonmetals. Metals are usually electrical conductors while non-metals are usually electrical insulators. Certain alloys and compounds may also have properties that are intermediate between metals and nonmetals.

The ion-implanted region may be amorphized. In various embodiments of the present invention, the ion-implanted species may include an element from column IV A of the periodic table, such as silicon or germanium. Silicon and germanium are metalloids that have semiconductor properties.

The ion-implanted region may be deep, shallow, or just below a surface 122 of the features of the layer 120 over the substrate 120. In an embodiment of the present invention, ion implantation may be performed with an energy of 15-35 keV. In an embodiment of the present invention, the ion implantation may be performed with an energy of 35-80 keV. In an embodiment of the present invention, the ion implantation may be performed with an energy of 80-200 keV. In an embodiment of the present invention, the ion implantation may be performed with an energy of 200-450 keV.

In an embodiment of the present invention, the ion implantation may be performed with a dose of 10⁹-10¹⁰ atoms/cm². In an embodiment of the present invention, the ion implantation may be performed with a dose of 10¹⁰-10¹¹ atoms/cm². In an embodiment of the present invention, the ion implantation may be performed with a dose of 10¹¹-10¹² atoms/cm². In an embodiment of the present invention, the ion implantation may be performed with a dose of 10¹²-10¹³ atoms/cm². The dose may include an integrated flux density. The atoms may include ions.

Third, a catalyst may be formed and placed at certain locations over the surface 222 of the layer 220, as shown in an embodiment of the present invention in FIG. 2. In an embodiment of the present invention, the locations may include an irregular or pseudo-random layout. In an embodiment of the present invention, the locations may include a regular or systematic layout.

The catalyst may be arranged in one or more ways, such as an isolated layout 501, a clustered layout 503, or a periodic layout 505 over the surface 222 of the layer 220. The periodic layout 505 may include a space 603 between adjacent locations of catalyst 602, 604.

In an embodiment of the present invention, nanowires that grow from a clustered layout 503 of catalyst may form a rope or bundle of nanowires (not shown). In an embodiment of the present invention, nanowires that grow from a clustered layout 503 of catalyst may merge or fuse into a large wire (not shown).

In an embodiment of the present invention, the areal density of the catalyst may include 10⁴-10⁶/cm². In an embodiment of the present invention, the areal density of the catalyst may include 10⁶-10⁸/cm². In an embodiment of the present invention, the areal density of the catalyst may include 10⁸-10¹⁰/cm². In an embodiment of the present invention, the areal density of the catalyst may include 10¹⁰-10¹²/cm².

After being formed and placed, the catalyst may include one or more discrete shapes, such as with sharp edges 404 or rounded edges 414, according to various embodiments of the present invention as shown in FIG. 1.

In an embodiment of the present invention, the catalyst may include an island, such as has been formed and placed by etching a discrete shape from a previously continuous film of catalyst. In an embodiment of the present invention, the catalyst may include a droplet or particle, such as has been formed and placed selectively and directly as a discrete shape.

After being formed and placed, the catalyst may include a footprint over the substrate. In an embodiment of the present invention, the catalyst islands (or particles) may include a polygonal (such as rectilinear or hexagonal) footprint over the substrate. In an embodiment of the present invention, the catalyst islands (or particles) may include a curved (such as circular or oval) footprint over the substrate.

In an embodiment of the present invention, a nanowire that grows from a catalyst with a doughnut-shaped (or ring-shaped) footprint may include a hollow core.

After being formed and placed, the catalyst may include one or more sizes. In an embodiment of the present invention, the catalyst islands (or particles) may include a size, such as a lateral dimension (such as width or diameter at the widest point) and a vertical dimension (such as thickness or height at the tallest point).

In an embodiment of the present invention, the lateral dimension of the catalyst may include 1-3 nanometers (nm). In an embodiment of the present invention, the lateral dimension of the catalyst may include 3-9 nm. In an embodiment of the present invention, the lateral dimension of the catalyst may include 9-25 nm. In an embodiment of the present invention, the lateral dimension of the catalyst may include 25-80 nm.

In an embodiment of the present invention, the vertical dimension of the catalyst may include 5-10 nm. In an embodiment of the present invention, the vertical dimension of the catalyst may include 10-15 nm. In an embodiment of the present invention, the vertical dimension of the catalyst may include 15-25 nm. In an embodiment of the present invention, the vertical dimension of the catalyst may include 25-40 nm.

In an embodiment of the present invention, the catalyst may include a material that may facilitate a chemical reaction, such as to form and place a nanowire, without being consumed itself.

Selection of a catalyst may depend on various factors, such as solubility in the layer 120 over the substrate 110, diffusion coefficient in the layer 120 over the substrate 110, or energy levels of band gap relative to the layer 120 over the substrate 110. In an embodiment of the present invention, a catalyst may have low solubility, low diffusion coefficient, and deep energy levels that are not at mid-gap.

In an embodiment of the present invention, the catalyst may include a metal. In different embodiments of the present invention, the catalyst may include an element from the lower portions of columns III A, IV A, or V A of the periodic table. In an embodiment of the present invention, the catalyst may include aluminum (Al) in column III A.

In an embodiment of the present invention, the catalyst may include a low-melting point metal. In different embodiments of the present invention, the low-melting point metal may include gallium (Ga) or Indium (In) from column III A of the periodic table. In an embodiment of the present invention, the low-melting point metal may include tin (Sn) from column IV A of the periodic table. In an embodiment of the present invention, the low-melting point metal may include bismuth (Bi) from column V A of the periodic table.

In an embodiment of the present invention, the catalyst may include a transition element. Transition elements have metallic properties and may also be called transition metals. Transition metals usually have a high melting point. Transition metals may include elements in columns IV B, V B, VI B, VII B, VIII B, and I B of the periodic table. In certain cases, the elements in columns III B and II B of the periodic table may be considered transition metals as well.

In an embodiment of the present invention, the catalyst may include an element from column IV B of the periodic table. In an embodiment of the present invention, the catalyst may include titanium (Ti).

In an embodiment of the present invention, the catalyst may include an element from column V B of the periodic table. In different embodiments of the present invention, the catalyst may include vanadium (V), niobium (Nb), or tantalum (Ta).

In an embodiment of the present invention, the catalyst may include an element from column VI B of the periodic table. In various embodiments of the present invention, the catalyst may include chromium (Cr), molybdenum (Mo), or tungsten (W).

In an embodiment of the present invention, the catalyst may include an element from column VII B of the periodic table. In an embodiment of the present invention, the catalyst may include manganese (Mn).

In an embodiment of the present invention, the catalyst may include an element from column VIII B of the periodic table. In various embodiments of the present invention, the catalyst may include iron (Fe), cobalt (Co), nickel (Ni), palladium (Pd), or platinum (Pt).

In an embodiment of the present invention, the catalyst may include an element from column I B of the periodic table. In various embodiments of the present invention, the catalyst may include copper (Cu), silver (Ag), or gold (Au).

In an embodiment of the present invention, the catalyst may include an element from column II B of the periodic table. In an embodiment of the present invention, the catalyst may include zinc (Zn).

In an embodiment of the present invention, the catalyst may include an alloy. In an embodiment of the present invention, the catalyst may include two or more metals.

In an embodiment of the present invention, the catalyst may include a metastable state, configuration, or form. In an embodiment of the present invention, the catalyst may include an intermetallic compound. In an embodiment of the present invention, the catalyst may include a liquid alloy or a molten alloy. In an embodiment of the present invention, the catalyst may include an eutectic.

In an embodiment of the present invention, the catalyst may include one or more metals and one or more non-metals. In an embodiment of the present invention, the catalyst may include a cermet.

In an embodiment of the present invention, the catalyst may include silicon. In different embodiments of the present invention, the catalyst may include a metal silicide, such as platinum silicide (PtSi), titanium silicide (TiSi₂), cobalt silicide (CoSi₂), or nickel silicide (Ni₂Si).

In an embodiment of the present invention, a subtractive patterning process, such as lithography and liftoff, may be used to form and place the catalyst. First, a photoresist may be formed over the substrate and patterned into a mask with lithography. Next, a continuous film of the catalyst may be formed non-selectively, such as by electron-beam evaporation, over the photoresist mask and the uncovered portions of the layer 220 over the substrate 210. The film should have good thickness uniformity and good conformality. Then, the photoresist with overlying portions of catalyst may be lifted off, leaving behind discrete shapes of catalyst over the uncovered portions of the layer 220 over the substrate 210.

In an embodiment of the present invention, a subtractive patterning process, such as lithography and etch, may be used to form and place the catalyst. First, a continuous film of the catalyst may be formed non-selectively, such as by chemical vapor deposition (CVD), over the layer 220 over the substrate 210. In an embodiment of the present invention, a precursor or reactant gas for CVD of the catalyst may include a metal source, such as metal halide, such as ferrous chloride (FeCl₂), ferric chloride (FeCl₃), or titanium chloride (TiCl₄). The film should have good thickness uniformity and good conformality. Next, a photoresist may be formed over the catalyst and patterned into an etch mask with lithography. Then, a dry or wet etch may be used to remove the unprotected portions of the catalyst, leaving behind discrete shapes of catalyst underlying the etch mask. Finally, the etch mask may be removed, such as by wet stripping or ashing.

In an embodiment of the present invention, a subtractive patterning process, such as lithography and etch, may be used to form and place the catalyst. First, a continuous film of the catalyst may be formed non-selectively, such as by CVD, over the layer 220 over the substrate 210. In an embodiment of the present invention, a precursor or reactant gas for CVD of the catalyst may include a metal source, such as metal halide, such as ferrous chloride (FeCl₂), ferric chloride (FeCl₃), or titanium chloride (TiCl₄). The film should have good thickness uniformity and good conformality. Next, a hard mask material may be formed, such as by CVD or physical vapor deposition (PVD or sputter deposition), over the catalyst.

The hard mask material may be stoichiometric or non-stoichiometric. In different embodiments of the present invention, the hard mask material may include a carbide, boride, or hydride. In other embodiments of the present invention, the hard mask material may include an oxide, nitride, or oxynitride.

Then, a photoresist may be formed over the hard mask material and patterned into an etch mask with lithography. A dry or wet etch may be used to transfer the photoresist pattern in the etch mask into an analogous pattern in the underlying hard mask material to form a hard mask. Finally, the etch mask may be removed, such as by wet stripping or ashing of the photoresist, leaving behind the underlying hard mask. Thus, openings with discrete shapes have been formed in the hard mask to uncover portions of the underlying continuous film of catalyst.

In an embodiment of the present invention, a dry or wet etch may be used to remove the hard mask material after nanowires have been formed over the portions of the catalyst uncovered by the openings in the hard mask. The catalyst that still remains between the nanowires may either be removed or left in place.

In another embodiment of the present invention, the hard mask material itself may be left in place after nanowires have been formed over the portions of the catalyst uncovered by the openings in the hard mask. In such a case, the catalyst still below the hard mask will remain embedded between the nanowires. Depending on the type of catalyst selected, the catalyst may serve as an electrical conductor between the nanowires.

In an embodiment of the present invention, an additive patterning process may be used to form and place the catalyst selectively and directly as discrete shapes, such as over certain locations of the exposed portions of the layer 220 over the substrate 210.

In an embodiment of the present invention, the catalyst may be formed by phase separation, such as by silicide phase separation. In an embodiment of the present invention, the catalyst may be formed as small, single-phase precipitates over silicide in the layer 220 over the substrate 210. In various embodiments of the present invention, the silicide may include a metal silicide, such as platinum silicide (PtSi), titanium silicide (TiSi₂), cobalt silicide (CoSi₂), or nickel silicide (Ni₂Si).

In an embodiment of the present invention, the catalyst may be formed by self-assembly in two dimensions. In an embodiment of the present invention, the catalyst may be formed by self-asembly of nanodots within a three-dimensional matrix (of other materials) that has been deposited, such as by pulsed-laser molecular beam epitaxy (MBE).

In an embodiment of the present invention, the catalyst may be formed as nano-particles using a wet chemistry process, such as solute precipitation from a dissolved solution or a colloidal solution. In an embodiment of the present invention, tin (Sn) may be directly deposited from a hydrogen peroxide (H₂O₂) solution. In an embodiment of the present invention, copper (Cu) may be directly deposited from a hydrofluoric (HF) acid solution.

In an embodiment of the present invention, the catalyst islands (or particles) may be further encapsulated with an interfacial film, such as a barrier layer. The encapsulation may be complete or partial. In an embodiment of the present invention, the barrier layer may prevent the catalyst from diffusing into another material. In an embodiment of the present invention, the barrier layer may prevent the catalyst from reacting with another material.

In an embodiment of the present invention, the barrier layer may include one or more elements from column IV B, V B, or VI B of the periodic table. In an embodiment of the present invention, the barrier layer may include silicon. In an embodiment of the present invention, the barrier layer may include nitride.

In an embodiment of the present invention, the barrier layer may include a single layer, such as with a thickness of 6-35 nm. In an embodiment of the present invention, the barrier layer may include a bi-layer, such as with a thickness of 10-25 nm. In an embodiment of the present invention, the barrier layer may include a multi-layer stack.

Fourth, a nanowire 2004 of a dielectric material, such as silicon nitride, may be formed at a catalyst island (or particle) 1404 over the layer 420 over the substrate 410, as shown in an embodiment of the present invention in FIG. 4. In an embodiment of the present invention, the dielectric material, such as silicon nitride, 1408 may be formed over the catalyst island (or particle) 1404 by using plasma-enhanced CVD (PECVD).

A reactor for PECVD may include a SEQUEL tool from Novellus Systems, Inc. When the layer 420 over the substrate 410 is exposed to appropriate precursors or reactant gases within the PECVD reactor, a dielectric material, such as silicon nitride, 1408 may nucleate at the catalyst island (or particle) and grow into a nanowire 2004. In an embodiment of the present invention, the reactant gases may include polymers or macromolecules.

In an embodiment of the present invention, the reactant gases may include a silicon source and a nitrogen source. In an embodiment of the present invention, a ratio of silicon source flowrate to nitrogen source flowrate may be selected from a range of 1:30-1:15. In an embodiment of the present invention, the ratio of silicon source flowrate to nitrogen source flowrate may be selected from a range of 1:15-1:6. In an embodiment of the present invention, the ratio of silicon source flowrate to nitrogen source flowrate may be selected from a range of 1:6-1:1. In an embodiment of the present invention, the ratio of silicon source flowrate to nitrogen source flowrate may be selected from a range of 1:1-2:1.

In an embodiment of the present invention, the silicon source may include silane (SiH₄). In an embodiment of the present invention, the silicon source may include dichlorosilane (SiCl₂H₂). In an embodiment of the present invention, the nitrogen source may include ammonia (NH₃). In an embodiment of the present invention, the nitrogen source may include nitrous oxide (N₂O). In an embodiment of the present invention, the nitrogen source may include nitrogen (N₂).

In an embodiment of the present invention, a diluent or carrier gas may be included. The carrier gas may include argon (Ar), helium (He), or nitrogen (N₂). The carrier gas may be used to decouple adjustment of the concentration of the reactant gases from adjustment of the flowrate of the reactant gases.

In an embodiment of the present invention, a reducing gas, such as hydrogen (H₂), may be included. In an embodiment of the present invention, the reducing gas may passivate a surface. In an embodiment of the present invention, the reducing gas may affect a surface tension of a material that is subsequently formed over the surface.

A total gas flowrate may include reactant gas flowrate, carrier gas flowrate, and reducing gas flowrate.

In an embodiment of the present invention, an areal density of the nanowires over the surface 420 of the substrate 410 may depend on the areal density of the catalyst islands (or particles) over the surface 420 of the substrate 410 since the catalyst may serve as seeds for deposition of a dielectric material, such as silicon nitride.

In an embodiment of the present invention, the areal density of the nanowires may include 10⁴-10⁶/cm². In an embodiment of the present invention, the areal density of the nanowires may include 10⁶-10⁸/cm². In an embodiment of the present invention, the areal density of the nanowires may include 10⁸-10¹⁰/cm². In an embodiment of the present invention, the areal density of the nanowires may include 10¹⁰-10¹²/cm².

In an embodiment of the present invention, the process parameters during formation of the nanowires may be tuned or optimized to determine the chemical, physical, optical, or mechanical properties of the nanowires. The process parameters for formation of the nanowires may include substrate temperature as a function of time, reactor pressure as a function of time, total (reactant, carrier, and reducing) gas flowrate, ratio of reactant gases as a function of time, timing of introduction of reactant gases, plasma power as a function of time, timing of ignition of plasma, and electric field (magnitude and orientation).

In an embodiment of the present invention, the properties of the nanowires may correlate with composition or stoichiometry of the material that forms the nanowires. In an embodiment of the present invention, the nanowires may include a dielectric material, such as silicon nitride, with properties, such as, density of 3.0-3.3 gm/cm³, refractive index of 1.80-2.30, band gap of 3.00-6.50 eV, Young's modulus of elasticity of 310-317 GPa, mechanical strength of 10⁰-10³ MPa (compressive or tensile), thermal conductivity of 0.15-0.30 W/cm-K, coefficient of thermal expansion of 3.0-3.4 ppm/C, dielectric constant of 4-8, dielectric strength of 10⁵-10⁷ V/cm, and electrical resistivity of about 10¹³ ohm-cm at room temperature.

In an embodiment of the present invention, the properties of a material, such as a dielectric, such as silicon nitride, in a bulk form may be significantly different from the properties of the material in a nanowire form. In an embodiment of the present invention, the properties of the material may change due to a quantum confinement effect. In an embodiment of the present invention, reducing the width or diameter of a nanowire below a threshold, such as 3 nm, may increase the band gap of the material that forms the nanowire.

The nanowire of a dielectric material, such as silicon nitride, may include one or more segments. In an embodiment of the present invention, the process parameters may be changed (completely) or modified (partially) before, during, or after formation of a segment of the nanowire. Consequently, the nanowire may include segments which differ, such as in structure, dimensions, morphology, phase, properties, composition, or stoichiometry. In various embodiments of the present invention, the segments of the nanowire may be (single) crystalline, polycrystalline, or amorphous.

The segments of the nanowire may be separated by transitions or interfaces. In an embodiment of the present invention, the process parameters may be modulated (according to the circumstances) gradually to form a smooth transition or interface between segments of the nanowire. In an embodiment of the present invention, the process parameters may be modulated (according to the circumstances) rapidly to form an abrupt transition or interface between segments of the nanowire.

In an embodiment of the present invention, the pressure in the PECVD reactor may be selected from a range such as 10⁻⁶-10⁻² Torr. In an embodiment of the present invention, the pressure in the PECVD reactor may be selected from a range such as 10⁻²-10² Torr.

In an embodiment of the present invention, the pressure in the PECVD reactor may include 1-5 Torr. In an embodiment of the present invention, the pressure in the PECVD reactor may include 5-20 Torr. In an embodiment of the present invention, the pressure in the PECVD reactor may include 20-60 Torr. In an embodiment of the present invention, the pressure in the PECVD reactor may include 60-120 Torr.

A dielectric material, such as silicon nitride, may be formed into nanowires at a low temperature to reduce stress and minimize distortion. Furthermore, the low temperature may permit a low deposition rate and, thus, better control over the properties of the dielectric material.

A plasma may be generated in the PECVD reactor by microwave or radio frequency (RF) energy, such as at 13.56 MHz to compensate for the low deposition temperature in a PECVD process. In an embodiment of the present invention, the power in the PECVD reactor may include 4-30 watts (W). In an embodiment of the present invention, the power in the PECVD reactor may include 30-200 W. In an embodiment of the present invention, the power in the PECVD reactor may include 200-800 W. In an embodiment of the present invention, the power in the PECVD reactor may include 800-1,500 W.

In an embodiment of the present invention, the dielectric material, such as silicon nitride, may be deposited with a PECVD process at a temperature selected from a range of 150-250 degrees Centigrade. In an embodiment of the present invention, the dielectric material, such as silicon nitride, may be deposited with a PECVD process at a temperature selected from a range of 250-350 degrees Centigrade. In an embodiment of the present invention, the dielectric material, such as silicon nitride, may be deposited with a PECVD process at a temperature selected from a range of 350-450 degrees Centigrade. In an embodiment of the present invention, the dielectric material, such as silicon nitride, may be deposited with a PECVD process at a temperature selected from a range of 450-550 degrees Centigrade.

In an embodiment of the present invention, the PECVD of the dielectric material, such as silicon nitride, may not be followed by an explicit (or dedicated) anneal. In an embodiment of the present invention, the PECVD of the dielectric material, such as silicon nitride, may be followed by one or more processes at temperatures higher than the deposition temperature that result in effects similar to those of an explicit (or dedicated) anneal. In an embodiment of the present invention, the PECVD of the dielectric material, such as silicon nitride, may be followed by an explicit (or dedicated) anneal to modify the segments of the nanowire, such as in structure, dimensions, morphology, phase, properties, composition, or stoichiometry.

In an embodiment of the present invention, the explicit (or dedicated) anneal may include a soak or duration of 1-4 minutes at a nominal anneal temperature. In an embodiment of the present invention, the explicit (or dedicated) anneal may include the duration of 4-12 minutes at the nominal anneal temperature. In an embodiment of the present invention, the explicit (or dedicated) anneal may include the duration of 12-24 minutes at the nominal anneal temperature. In an embodiment of the present invention, the explicit (or dedicated) anneal may include the duration of 24-60 minutes at the nominal anneal temperature.

In an embodiment of the present invention, the explicit (or dedicated) anneal may be performed in an oxidizing environment, such as including oxygen (O₂) or water (H₂O). In an embodiment of the present invention, the anneal may be performed in a reducing environment, such as including hydrogen (H₂). In an embodiment of the present invention, the anneal may be performed in an inert environment, such as including argon (Ar), helium (He), or nitrogen (N₂).

In an embodiment of the present invention, the anneal may be performed at a temperature below 400 degrees Centigrade. In an embodiment of the present invention, the anneal may be performed at a temperature selected from a range of 400-600 degrees Centigrade. In an embodiment of the present invention, the anneal may be performed at a temperature above 600 degrees Centigrade.

In an embodiment of the present invention, the anneal temperature may be less than 200 degrees Centigrade above the highest deposition temperature. In an embodiment of the present invention, the anneal temperature may be selected from a range of 200-300 degrees Centigrade above the highest deposition temperature. In an embodiment of the present invention, the anneal temperature may be more than 300 degrees Centigrade above the highest deposition temperature.

In an embodiment of the present invention, the nanowire of a dielectric material, such as silicon nitride, may be formed with a deposition temperature of 200 degrees Centigrade and an anneal temperature of 350 degrees Centigrade. In an embodiment of the present invention, the nanowire of a dielectric material, such as silicon nitride, may be formed with a deposition temperature of 300 degrees Centigrade and an anneal temperature of 550 degrees Centigrade. In an embodiment of the present invention, the nanowire of a dielectric material, such as silicon nitride, may be formed with a deposition temperature of 400 degrees Centigrade and an anneal temperature of 750 degrees Centigrade.

In an embodiment of the present invention, the nanowire of a dielectric material, such as silicon nitride, may be formed with a deposition temperature of 400 degrees Centigrade without any explicit (or dedicated) anneal.

In an embodiment of the present invention, the nanowire of a dielectric material, such as silicon nitride, may be formed at two or more deposition temperatures, such as at 200 and 400 degrees Centigrade.

In an embodiment of the present invention, the formation of the nanowires over the catalyst islands (or particles) may be dominated by reaction rate or kinetics. In an embodiment of the present invention, the formation of the nanowires may be limited by catalytic decomposition of one or more of the reactant gases. In an embodiment of the present invention, the formation of the nanowires may be limited by catalytic decomposition of the silicon source, such as silane. In an embodiment of the present invention, the formation of the nanowires may be limited by catalytic decomposition of the nitrogen source, such as ammonia.

In an embodiment of the present invention, the formation of the nanowires over the catalyst islands (or particles) may be dominated by mass transfer. In an embodiment of the present invention, the formation of the nanowires may be limited by diffusion in a vapor or gas phase in the PECVD reactor.

In an embodiment of the present invention, the formation of the nanowires may be limited by surface mobility over the nanowire or the catalyst.

In an embodiment of the present invention, the formation of the nanowires may be limited by diffusion in a solid state, such as within the nanowire. In an embodiment of the present invention, the solid-state diffusion may involve movement of substitutional atoms or interstitial atoms. In an embodiment of the present invention, the solid-state diffusion may involve movement of vacancies at dislocations or boundaries.

In an embodiment of the present invention, the formation of the nanowires may be limited by phase segregation as mediated by the catalyst.

Distinct growth modes for the nanowire may exist alternatively, concurrently, or sequentially. In various embodiments of the present invention to achieve a certain length for a nanowire, the nanowire may grow at a tip, a base (or root), both the tip and the base (mixed), or neither the tip nor the base (indeterminate). In an embodiment of the present invention, selecting a reaction-rate-limited growth regime or a mass-transfer limited growth regime for formation of the nanowire in the PECVD reactor may determine the growth mode. In an embodiment of the present invention, choice of material for the catalyst may determine the growth mode. In an embodiment of the present invention, adjusting one or more process parameters, such as temperature, for formation of the nanowire in the PECVD reactor may determine whether growth occurs at the tip or at the base (or root) of the nanowire.

In an embodiment of the present invention as shown in FIG. 4, such as may correspond to tip growth, a nanowire 2004 of a dielectric material, such as silicon nitride, may include a catalyst, such as a metal or an alloy, 1404 at or near its base (or root). In an embodiment of the present invention, such as may correspond to base (or root) growth, a nanowire 2006 of a dielectric material, such as silicon nitride, may include a catalyst, such as a metal or an alloy, 2404 at or near its tip. In an embodiment of the present invention, such as may correspond to mixed or indeterminate growth, a nanowire of a dielectric material, such as silicon nitride, may include a catalyst, such as a metal or an alloy, in an intermediate region 2406 between its base (or root) and its tip.

In an embodiment of the present invention, the length of the nanowire may be achieved by adjusting a total growth (or “on” contact) time. In an embodiment of the present invention, the total growth time may be selected from a range such as 6-20 seconds. In an embodiment of the present invention, the total growth time may be selected from a range such as 20-60 seconds. In an embodiment of the present invention, the total growth time may be selected from a range such as 60-120 seconds. In an embodiment of the present invention, the total growth time may be selected from a range such as 120-240 seconds.

In an embodiment of the present invention, the growth may be continuous (uninterrupted) and unified into a single extended “on” pulse. In an embodiment of the present invention, the growth may be continual (intermittent) and recurring over multiple “on” pulses separated by “off” pulses.

In an embodiment of the present invention, the process parameters may vary during a pulse, whether “on” or “off”. In an embodiment of the present invention, the process parameters may vary between distinct pulses, whether “on” or “off”.

In an embodiment of the present invention, the length of the nanowire may be achieved by adjusting a growth rate. In an embodiment of the present invention, the growth rate may be selected from a range such as 1-8 nm/minute. In an embodiment of the present invention, the growth rate may be selected from a range such as 8-30 nm/minute. In an embodiment of the present invention, the growth rate may be selected from a range such as 30-90 nm/minute. In an embodiment of the present invention, the growth rate may be selected from a range such as 90-180 nm/minute.

In an embodiment of the present invention, the length of the nanowire may be achieved by adjusting reactant gas concentration. In an embodiment of the present invention, the length of the nanowire may be achieved by adjusting reactant gas flowrate.

In an embodiment of the present invention, a segment of a nanowire may include a characteristic spatial arrangement and a characteristic orientation angle. In an embodiment of the present invention, the spatial arrangement only, the orientation angle only, or both the spatial arrangement and the orientation angle may be determined, such as by choice of process parameters, during growth of the nanowire. In an embodiment of the present invention, the spatial arrangement only, the orientation angle only, or both the spatial arrangement and the orientation angle may be altered, such as by inclusion of subsequent processing, after growth of the nanowire.

In an embodiment of the present invention, the spatial arrangement or orientation angle of one or more segments of the nanowire may be determined or altered by thermally treating or annealing at a certain temperature. In an embodiment of the present invention, the spatial arrangement or orientation angle of one or more segments of the nanowire may be determined or altered by aligning in an electric field, such as may be established in-situ during growth of the nanowire in the PECVD reactor. In an embodiment of the present invention, the spatial arrangement or orientation angle of one or more segments of the nanowire may be determined or altered by aligning rheologically in a fluid, such as a liquid or a gas. Alignment in a liquid may involve use of a surfactant to separate the nanowires. In an embodiment of the present invention, the spatial arrangement or orientation angle of one or more segments of the nanowire may be determined or altered by applying strain externally or internally to the segments of the nanowire.

Next, a segmented nanowire of a dielectric material, such as silicon nitride, located over a substrate according to various embodiments of the present invention will be described.

In an embodiment of the present invention, the nanowire of a dielectric material, such as silicon nitride, may be homogeneous. In an embodiment of the present invention, the nanowire of a dielectric material, such as silicon nitride, may be heterogeneous.

In an embodiment of the present invention, the process parameters during formation of a nanowire may affect the properties of the nanowire. The nanowire may be characterized by chemical, physical, optical, or mechanical properties. In an embodiment of the present invention, the nanowires may include a dielectric material, such as silicon nitride, with properties, such as, density of 3.0-3.3 gm/cm³, refractive index of 1.80-2.30, band gap of 3.00-6.50 eV, Young's modulus of elasticity of 310-317 GPa, mechanical strength of 10⁰-10³ MPa (compressive or tensile), thermal conductivity of 0.15-0.30 W/cm-K, coefficient of thermal expansion of 3.0-3.4 ppm/C, dielectric constant of 4-8, dielectric strength of 10⁵-10⁷ V/cm, and electrical resistivity of about 10¹³ ohm-cm at room temperature.

In an embodiment of the present invention, the properties of a material, such as a dielectric, such as silicon nitride, in a bulk form may be significantly different from the properties of the material in a nanowire form. In an embodiment of the present invention, the properties of the material may change due to a quantum confinement effect. In an embodiment of the present invention, reducing the width or diameter of a nanowire below a threshold, such as 3 nm, may increase the band gap of the material that forms the nanowire.

In an embodiment of the present invention, the properties of the dielectric material may correlate with composition or stoichiometry. In an embodiment of the present invention, the nanowire may include a dielectric material, such as silicon nitride, that may be stoichiometric, such as Si₃N₄. In an embodiment of the present invention, the nanowire may include a dielectric material, such as silicon nitride, that may be non-stoichiometric, such as SiₓN_{y}.

In an embodiment of the present invention, an atomic ratio of N:Si (or y:x) may include 0.90-1.05. In an embodiment of the present invention, the N:Si ratio may include 1.05-1.20. In an embodiment of the present invention, the N:Si ratio may include 1.20-1.35. In an embodiment of the present invention, the N: Si ratio may include 1.35-1.50.

In an embodiment of the present invention, the dielectric material in the nanowire may be formed from certain primary elements, such as silicon and nitrogen. In an embodiment of the present invention, the dielectric material in the nanowire may further be formed from small quantities of one or more secondary elements, such as hydrogen, carbon, oxygen, phosphorous, or sulfur. In an embodiment of the present invention, a secondary element, such as hydrogen, may be derived from a reactant gas, such as due to decomposition of a silicon source.

In an embodiment of the present invention, a small quantity of a secondary element may include an atomic ratio of the secondary element to a primary element, such as silicon, of 0.02 or less. In an embodiment of the present invention, a small quantity of the secondary element may include an atomic ratio of the secondary element to a primary element, such as silicon, of 0.06 or less. In an embodiment of the present invention, a small quantity of the secondary element may include an atomic ratio of the secondary element to a primary element, such as silicon, of 0.15 or less. In an embodiment of the present invention, a small quantity of the secondary element may include an atomic ratio of the secondary element to a primary element, such as silicon, of 0.30 or less.

In an embodiment of the present invention, the nanowire of a dielectric material, such as silicon nitride, may be connected to a substrate. In an embodiment of the present invention as shown in FIG. 1, the substrate 110 may include a surface 122. The surface 122 may include features. The features may be protruding 302, recessed 306, or flush 304 with the surface 122. The features may include grooves, holes, or steps. The walls of the features may meet the surface 122 at angles that may be acute, right, or obtuse. In an embodiment of the present invention, the nanowire of a dielectric material, such as silicon nitride, may be connected to one or more features of the substrate.

In an embodiment of the present invention, the nanowire of a dielectric material, such as silicon nitride, and the substrate may contact each other directly. In an embodiment of the present invention, the nanowire of a dielectric material, such as silicon nitride, and the substrate may be linked through an intermediary structure. In an embodiment of the present invention, the nanowire of a dielectric material, such as silicon nitride, and the substrate may be united or fused to form a single structure.

In an embodiment of the present invention, one portion of the nanowire of a dielectric material, such as silicon nitride, may be attached to the substrate. In an embodiment of the present invention, one end of the nanowire of a dielectric material, such as silicon nitride, may be attached to the substrate. In an embodiment of the present invention, two or more portions of the nanowire of a dielectric material, such as silicon nitride, may be attached to the substrate.

In an embodiment of the present invention, the substrate may include a material that is homogeneous. In an embodiment of the present invention, the substrate may include two or more chemically or physically distinct materials. In an embodiment of the present invention, the substrate may include a patterned stack of two or more materials.

In an embodiment of the present invention, the substrate may include an electrical conductor, such as copper. In an embodiment of the present invention, the substrate may include an electrical insulator, such as low-k (dielectric constant) material. In an embodiment of the present invention, the substrate may include a semiconductor, such as silicon-germanium. In an embodiment of the present invention, the substrate may be doped.

In an embodiment of the present invention, the substrate may include an electrical conductor, such as copper. In an embodiment of the present invention, the substrate may include an electrical insulator, such as low-k (dielectric constant) material. In an embodiment of the present invention, the substrate may include a semiconductor, such as silicon-germanium. In an embodiment of the present invention, the substrate may be doped.

In an embodiment of the present invention, the substrate may include a semiconductor wafer. In an embodiment of the present invention, the substrate may include a silicon-on-insulator (SOI) wafer. In an embodiment of the present invention, the substrate may include an integrated circuit (IC) chip or die. In an embodiment of the present invention, the substrate may include bonded wafers. In an embodiment of the present invention, the substrate may include stacked chips. In an embodiment of the present invention, the substrate may include a package. In an embodiment of the present invention, the substrate may include a microelectromechanical system (MEMS).

The nanowire of a dielectric material, such as silicon nitride, may include one or more segments. The nanowire may include segments which differ, such as in structure, dimensions, morphology, phase, properties, composition, or stoichiometry. In various embodiments of the present invention, the segments of the nanowire may be (single) crystalline, polycrystalline, or amorphous.

The segments of the nanowire may be separated by transitions or interfaces. In an embodiment of the present invention, each segment of the nanowire of a dielectric material, such as silicon nitride, may include a characteristic shape, cross-section, interior portion, exterior portion, spatial arrangement, orientation angle, stiffness, smaller dimension, and larger dimension.

Each segment of the nanowire of a dielectric material, such as silicon nitride, may include a characteristic shape. In an embodiment of the present invention, the shape may include linear or unbranched portions. In an embodiment of the present invention, the shape may include branched portions. In an embodiment of the present invention, the shape may include cyclic portions. In an embodiment of the present invention, the shape may include cage portions.

Each segment of the nanowire of a dielectric material, such as silicon nitride, may include a characteristic cross-section. In an embodiment of the present invention, the cross-section may be polygonal (such as triangular, rectilinear, or hexagonal). In an embodiment of the present invention, the cross-section may be curved (such as circular or oval).

Each segment of the nanowire of a dielecric material, such as silicon nitride, may include a characteristic inner or interior portion, or core. In an embodiment of the present invention, the core of the nanowire may include a hollow cavity, thus forming a nanotube. In an embodiment of the present invention, the core may be solid. In an embodiment of the present invention, the core may be porous with a porosity of 15-35% by volume. The pores may include various sizes. In an embodiment of the present invention, the pores may be closed. In an embodiment of the present invention, the pores may be interconnected.

Each segment of the nanowire of a dielectric material, such as silicon nitride, may include a characteristic outer or exterior portion, or cladding. In an embodiment of the present invention, the cladding may be solid. In an embodiment of the present invention, the cladding may be porous with a porosity of 15-35% by volume. The pores may include various sizes. In an embodiment of the present invention, the pores may be closed. In an embodiment of the present invention, the pores may be interconnected.

Each segment of the nanowire of a dielectric material, such as silicon nitride, may include a characteristic spatial arrangement, as shown in an embodiment of the present invention in FIG. 3. In an embodiment of the present invention, the spatial arrangement may include straight portions 801. In an embodiment of the present invention, the spatial arrangement may include bent or crooked portions 802 with elbows. In an embodiment of the present invention, the spatial arrangement may include folded or overlapped portions 803. In an embodiment of the present invention, the spatial arrangement may include curved or wavy portions 804. In an embodiment of the present invention, the spatial arrangement may include winding or sinuous portions 805. In an embodiment of the present invention, the spatial arrangement may include coil, spiral, or helical portions 806.

A segment 805 of the nanowire 1001 of a dielectric material, such as silicon nitride, may be considered to be located along (or arranged around) a primary axis (or hypothetical backbone) 807 that, when extended, has a characteristic orientation angle 808 with respect to an equivalent (geometric) plane 809 within which is located a surface 320 of the substrate 310. In certain cases, the primary axis 807 may go through both ends of the segment 805, such as a transition or interface 903 and a tip 707.

In an embodiment of the present invention, the primary axis of a segment of a nanowire of a dielectric material, such as silicon nitride, may include a characteristic orientation angle (of 90 degrees) that is perpendicular to the equivalent plane of the surface of the substrate. In an embodiment of the present invention, the primary axis of the segment of the nanowire of a dielectric material, such as silicon nitride, may include a characteristic orientation angle (of zero degree) that is parallel to the equivalent plane of the surface of the substrate. In an embodiment of the present invention, the primary axis of the segment of a nanowire of a dielectric material, such as silicon nitride, may include a characteristic orientation angle selected from a range of 0-90 degrees. In an embodiment of the present invention, a segment of the nanowire of a dielectric material, such as silicon nitride, may not include a readily discernible primary axis since the segment may be folded or overlapped 803 or otherwise distorted.

Each segment of the nanowire of a dielectric material, such as silicon nitride, may include a characteristic stiffness. In an embodiment of the present invention as shown in FIG. 4, the nanowire may be rigid with a high stiffness (such as a rod or pillar) 2002. In an embodiment of the present invention, the nanowire may be flexible with a low stiffness (such as a filament or ribbon) 2004, 2006.

Each segment 3408 of the nanowire of a dielectric material, such as silicon nitride, may include a characteristic smaller (such as lateral or radial) dimension 3401 such as may be analogous to a width or diameter. In an embodiment of the present invention, the smaller dimension 3401 may include 1-3 nm. In an embodiment of the present invention, the smaller dimension 3401 may include 3-9 nm. In an embodiment of the present invention, the smaller dimension may include 9-25 nm. In an embodiment of the present invention, the smaller dimension 3401 may include 25-80 nm.

Each segment 3408 of the nanowire of a dielectric material, such as silicon nitride, may include a characteristic larger (such as longitudinal or axial) dimension 3403 such as may be analogous to a length. In an embodiment of the present invention, the larger dimension 3403 may include 0.006-0.050 micron (um). In an embodiment of the present invention, the larger dimension 3403 may include 0.050-0.400 um. In an embodiment of the present invention, the larger dimension 3403 may include 0.400-3.000 um. In an embodiment of the present invention, the larger dimension 3403 may include 3.000-25.000 um.

Each segment of the nanowire of a dielectric material, such as silicon nitride may include an aspect ratio of the smaller (such as lateral or radial) dimension 3401 relative to the larger (such as longitudinal or axial) dimension 3403. In an embodiment of the present invention, the aspect ratio may include 1:3 to 1:20. In an embodiment of the present invention, the aspect ratio may include 1:20 to 1:125. In an embodiment of the present invention, the aspect ratio may include 1:125 to 1:800. In an embodiment of the present invention, the aspect ratio may include 1:800 to 1:7,500.

In an embodiment of the present invention as shown in FIG. 3, the nanowire of a dielectric material, such as silicon nitride, may include a base (or root) 701. The base (or root) 701 may include an end of the nanowire that is nearest or closest to a point of connection or attachment of the nanowire to the layer 320 over the substrate 310.

In an embodiment of the present invention, the nanowire of a dielectric material, such as silicon nitride, may include a tip 707. The tip 707 may include an end of the nanowire that is furthest or most distant from a point of connection or attachment of the nanowire to the layer 320 over the substrate 310.

In various embodiments of the present invention, the growth of the nanowire may have occurred at the tip, at the base (or root), at both the tip and the base (mixed), or at neither the tip nor the base (indeterminate).

In an embodiment of the present invention corresponding to tip growth, a nanowire 2004 of a dielectric material, such as silicon nitride, may include a catalyst, such as a metal or an alloy, 1404 at or near its base (or root).

In an embodiment of the present invention corresponding to base (or root) growth, a nanowire 2006 of a dielectric material, such as silicon nitride, may include a catalyst, such as a metal or an alloy, 2404 at or near its tip.

In an embodiment of the present invention corresponding to mixed or indeterminate growth, a nanowire (not shown) of a dielectric material, such as silicon nitride, may include a catalyst, such as a metal or an alloy, in an intermediate region 2406 between its base (or root) and its tip.

In an embodiment of the present invention, a nanowire of a dielectric material, such as silicon nitride, may include a catalyst, such as a metal or an alloy, embedded 3404 in a layer 420 over the substrate 410. In an embodiment of the present invention, the embedded catalyst, such as a metal or an alloy, 3404 may occupy part or all of a feature in the layer 420 over the substrate 410.

An array of nanowires may include two or more nanowires of a dielectric material, such as silicon nitride, that are connected or attached to a substrate and that are separated by spaces. The array may be two-dimensional or three-dimensional. In an embodiment of the present invention, the nanowires of a dielectric material, such as silicon nitride, in the array may be similar. In an embodiment of the present invention, the spaces between the nanowires of a dielectric material, such as silicon nitride, in the array may be similar.

In an embodiment of the present invention, the areal density of the nanowires may include 10⁴-10⁶/cm². In an embodiment of the present invention, the areal density of the nanowires may include 10⁶-10⁸/cm². In an embodiment of the present invention, the areal density of the nanowires may include 10⁸-10¹⁰/cm². In an embodiment of the present invention, the areal density of the nanowires may include 10¹-10¹²/cm².

In an embodiment of the present invention, the locations may include an irregular or pseudo-random layout. In an embodiment of the present invention, the locations may include a regular or systematic layout. The catalyst may be arranged in one or more ways, such as an isolated layout 501, a clustered layout 503, or a periodic layout 505. The periodic layout 505 may include a space 603 between adjacent locations of catalyst 602, 604.

In an embodiment of the present invention, a periodic array of nanowires of a dielectric material, such as silicon nitride, may have a layout with a pitch that may be defined as a sum of the characteristic smaller (such as radial) dimension of the nanowire, such as may be analogous to a width or diameter, and the space between adjacent nanowires.

In an embodiment of the present invention, the space between adjacent nanowires of a dielectric material, such as silicon nitride, may include 2-10 nm. In an embodiment of the present invention, the space between adjacent nanowires of a dielectric material, such as silicon nitride, may include 1040 nm. In an embodiment of the present invention, the space between adjacent nanowires of a dielectric material, such as silicon nitride, may include 40-120 nm. In an embodiment of the present invention, the space between adjacent nanowires of a dielectric material, such as silicon nitride, may include 120-240 nm.

In an embodiment of the present invention, the ratio of the space relative to the smaller dimension may include 0.2-1.0. In an embodiment of the present invention, the ratio of the space relative to the smaller dimension may include 1.0-5.0. In an embodiment of the present invention, the ratio of the space relative to the smaller dimension may include 5.0-25.0. In an embodiment of the present invention, the ratio of the space relative to the smaller dimension may include 25.0-125.0.

Many embodiments and numerous details have been set forth above in order to provide a thorough understanding of the present invention. One skilled in the art will appreciate that many of the features in one embodiment are equally applicable to other embodiments. One skilled in the art will also appreciate the ability to make various equivalent substitutions for those specific materials, processes, dimensions, concentrations, etc. described herein. It is to be understood that the detailed description of the present invention should be taken as illustrative and not limiting, wherein the scope of the present invention should be determined by the claims that follow.

Thus, we have described a method of forming a segmented nanowire of a dielectric material, such as silicon nitride, and such a segmented nanowire of a dielectric material, such as silicon nitride.

1. A method of forming a segmented nanowire comprising:
providing a substrate;
pre-cleaning said substrate;
pre-treating said substrate;
forming and placing a catalyst over said substrate; and
forming said segmented nanowire over said catalyst with recurring pulses of plasma-enhanced chemical vapor deposition (PECVD) of a dielectric material.

2. The method of claim 1 wherein said dielectric material comprises silicon nitride with some hydrogen.

3. The method of claim 1 wherein said dielectric material comprises silicon nitride that is not stoichiometric.

4. The method of claim 1 wherein said PECVD comprises a deposition temperature of 350-450 degrees Centigrade.

5. The method of claim 1 further comprising annealing said nanowire.

6. The method of claim 1 further comprising ion implanting said substrate prior to forming and placing said catalyst.

7. A method of forming an array of nanowires having a length comprising:
providing a substrate, said substrate having a layer, said layer having a surface, said surface having features;
pre-cleaning said substrate;
pre-treating said substrate;
forming a catalyst over said substrate;
patterning said catalyst over said features;
selecting a first set of process parameters;
forming a first segment over said catalyst;
selecting a second set of process parameters;
forming a second segment over said first segment; and
alternating between selecting another set of process parameters and forming another segment until said length has been achieved.

8. The method of claim 7 wherein said first segment is formed with plasma-enhanced chemical vapor deposition (PECVD) of a dielectric material.

9. The method of claim 7 further comprising aligning said nanowires in said array.

10. The method of claim 7 wherein said first segment is formed by tip growth.

11. The method of claim 7 wherein said first segment is formed by base (or root) growth.

12. The method of claim 7 wherein said first segment is formed by mixed growth.

13. A nanowire of dielectric material comprising a plurality of segments wherein each segment may include a characteristic shape, cross-section, interior portion, exterior portion, spatial arrangement, orientation angle, stiffness, smaller dimension, and larger dimension.

14. The nanowire of claim 10 wherein said dielectric material comprises silicon nitride with some hydrogen.

15. The nanowire of claim 10 wherein said smaller dimension, such as may be analogous to a width or a diameter, may include 1-3 nanometers.

16. The nanowire of claim 10 wherein said larger dimension, such as may be analogous to a length, may include 0.006-0.050 microns.

17. The nanowire of claim 10 wherein said nanowire forms part of an array of nanowires.

18. The nanowire of claim 14 wherein said array further comprises spaces between adjacent nanowires.

19. The nanowire of claim 14 further comprising a catalyst at or near its base (or root).

20. The nanowire of claim 14 further comprising a catlyst at or near its tip.
